(19) United States
(12) Patent Application Publication
(10) Pub. No.: US 2024/0303398 A1
(43) Pub. Date: Sep. 12, 2024

(54) ABNORMAL PRESSURE DETECTION USING ONLINE BAYESIAN LINEAR REGRESSION

(71) Applicant: Schlumberger Technology Corporation, Sugar Land, TX (US)

(72) Inventors: Tao Shen, Beijing (CN); Jia Xu Liu, Beijing (CN); Florian Le Blay, Beijing (CN); Samba Ba, Houston, TX (US); Xin Chen, Beijing (CN)

(21) Appl. No.: 18/261,306

(22) PCT Filed: Jan. 17, 2022
(86) PCT No.: PCT/US2022/070213

§ 371 Date: Jul. 13, 2023

Related U.S. Application Data
(60) Provisional application No. 63/199,663, filed on Jan. 15, 2021.
(60) Provisional application No. 63/199,664, filed on Jan. 15, 2021.

(51) Int. Cl. G06F 30/27; E21B 21/08; E21B 47/04

(52) U.S. Cl. CPC G06F 30/27; E21B 21/08; E21B 47/04; E21B 2200/20

(57) ABSTRACT

A method and a processing device are provided for predicting standpipe pressure. A Bayesian linear regressor is initialized. Priors for the Bayesian linear regressor are initialized based on previous drilling operations that used a same bottom hole assembly. Measurement data associated with drilling a well is received in real time. An online Bayesian linear regressor update is generated using QR decomposition for a model. Responsive to determining that at least some coefficients violate physical rules, the at least some of the coefficients are set to a respective default value that is either zero or a positive value. Coefficients and uncertainty are updated based on at least one of the online Bayesian linear regressor update and the setting of at least some of the coefficients. The model is then visualized. Visualization helps a user identify whether the learned model makes sense.

### CROSS REFERENCE PARAGRAPH

This application claims the benefit of U.S. Provisional Application No. 63/199,663, entitled “ABNORMAL PRESSURE DETECTION USING ONLINE BAYESIAN LINEAR REGRESSION,” filed Jan. 15, 2021, and U.S. Provisional Application No. 63/199,664, entitled “ABNORMAL PRESSURE DETECTION USING MACHINE LEARNING,” filed Jan. 15, 2021, the disclosure of which is hereby incorporated herein by reference.

### BACKGROUND

During drilling, standpipe pressure may be calculated and modeled. For example, some workflows may provide pressure prediction models, which may distinguish rotating mode, in which a drill string is rotated, from sliding mode, in which a distal portion of the string or the bit is rotated without rotating the remainder of the drill string. A pressure prediction workflow may then assign data to corresponding sub-models and predict the standpipe pressure. If the pressure is anomalous (too high or too low) an alarm may be triggered. Such workflows may also calibrate the models.

Different models are fed with data in an unbalanced way. In the pressure prediction workflow, data may be fed whether in rotating mode or in sliding mode. As a consequence, a model associated with the active drilling mode may be updated, and another model may not be updated. This can lead to feeding one model more, and updating that model more than the other model, which may lead to false alarms. Further, calibration may be unstable and slow. For example, it may be difficult to find a calibration point for a long period of time or at various points during drilling operations. This results in disfunction for the existing workflow because few or no results may be computed. Second, calibration points provide the input to the models, but the data used to generate a calibration point normally represents a small percentage (less than 10%) of entire received data. In other words, at least 90% of received data have been dropped without being exploited by the workflow.

A Gaussian process may be used to detect existing abnormal pressure workflows in post-processing of the data to generate a chart illustrating a relationship between standpipe pressure and flowrate, torque, and weight on bit. However, utilizing a Gaussian process introduces non-interpretability and may cause some basic physical properties to become broken.

Other methods for pressure prediction may estimate coefficients. For example, by using linear regression (or ridge regression), kernel regression or a Gaussian process, data can be consumed, a model can be fitted (for Linear Regression or Ridge Regression), and a prediction value can be obtained. However, linear regression (or ridge regression) and kernel regression may not yield estimates with an uncertainty value. Further, using kernel regression or a Gaussian process fails to provide an explicit model. As a result, it may be difficult to physically interpret the results. Moreover, these methods may provide results that violate the laws of physics.

### BRIEF DESCRIPTION OF THE DRAWINGS

The accompanying drawings, which are incorporated in and constitute a part of this specification, illustrate embodiments of the present teachings and together with the description, serve to explain the principles of the present teachings. In the figures:

FIG. 1 illustrates an example of a system that includes various management components to manage various aspects of a geologic environment, according to an embodiment.

FIG. 2 illustrates a flowchart of a method for predicting standpipe pressure, according to an embodiment.

FIG. 3 illustrates a more detailed flowchart of an embodiment of the method, according to an embodiment.

FIG. 4 illustrates a mathematical model for abnormal pressure detection, according to an embodiment.

FIG. 5 illustrates a schematization of an embodiment of a grouping recursive Bayesian network (GRBN) workflow.

FIG. 6 illustrates an embodiment of a recursive Bayesian network (RBN) consuming streaming data.

FIG. 7 illustrates one embodiment of an approach to ensemble learning.

FIG. 8 illustrates an embodiment of an evolutionary mechanism in which a limited number of models are kept as enlisted models.

FIG. 9 shows the Kullback-Leibler divergence, which may be used to select a model.

FIG. 10 illustrates one approach to a grouping recursive Bayesian Network (GRBN) system operating on streaming data according to various embodiments.

FIG. 11 illustrates an approach, in one embodiment, regarding how enlisted models may be in groupings as a system evolves.

FIGS. 12, 13, and 14 are flowcharts that illustrate processing with respect to GRBN in various embodiments.

FIG. 15 illustrates a schematic view of a computing system, according to an embodiment.

FIG. 16 illustrates a schematic view of another computing system, according to an embodiment.

### SUMMARY

Embodiments of the present disclosure may provide a method for predicting standpipe pressure. A Bayesian linear regressor is initialized. Priors for the Bayesian linear regressor are initialized based on previous drilling operations that use the same bottom hole assembly. Measurement data associated with drilling a well is received in real time. An online Bayesian linear regressor update is generated using QR (where Q is a matrix having orthonormal columns and R is an upper triangular matrix) decomposition for a model. Whether coefficients of the online Bayesian aggressor update violate physical rules is determined. Responsive to determining that at least some of the coefficients violate the physical rules, the at least some of the coefficients are set to respective default values that are either zero or a positive value. Coefficients and uncertainty are updated based on the online Bayesian linear regressor update or the setting of the at least some of the coefficients. The model is then visualized

In an embodiment, the method may include applying an infinite impulse response filter to the received measurement data to the noise the received measurement data.

In an embodiment of the method, the received measurement data includes standpipe pressure, flow rate, bit depth, surface weight on bit, and torque.

In an embodiment of the method, the QR decomposition extracts a column from an ill-positioned matrix to form a well-positioned sub-matrix, which is used to solve a matrix inversion equation with numerical stability.

In an embodiment of the method, respective coefficients of the at least some of the coefficients conform to the physical rules when corresponding values of the respective coefficients fall within corresponding valid ranges of values.

Embodiments of the present disclosure may also provide at least one processing device for predicting a standpipe pressure. Each of the at least one processing device includes at least one processor, and a memory connected with the at least one processor. The memory includes instructions for the at least one processor to perform multiple operations. According to the operations, values of coefficients are initialized for a model. The model is created with the initialized coefficients as an enlisted model. Until a number of listed models is a preset number, performing: receiving of measured data during the next time interval; updating all candidate models based on received metadata; creating a candidate model based on the received measured data; dropping the candidate model when at least one coefficient of the candidate model violated a physical rule; and making the candidate model an enlisted model when all coefficients of the candidate model comply with the physical rule and the current number of enlisted models is less than the preset number. The standpipe pressure is predicted based on the enlisted models by applying a corresponding weight to a predicted standpipe pressure of each respective enlisted model to produce a respective weighted predicted standpipe pressure, wherein the corresponding weight is based on an inverse of a variance or a standard deviation of the respective enlisted model over a corresponding time interval. The respective weighted predicted standpipe pressures are added to produce a sum of the weighted pressures. The sum of the weighted pressures is divided by a sum of the weights to produce a predicted standpipe pressure based on the preset number of the enlisted models.

In an embodiment of the at least one processing device, the creating of the candidate model based on the received measured data further includes creating the candidate model only when at least a preset period of time has passed since creation of a last model.

In an embodiment of the at least one processing device, the creating of the candidate model based on the received measured data further includes creating the candidate model with default coefficients.

In an embodiment of the at least one processing device, wherein the creating of the candidate model based on the received measured data further includes creating the candidate model with default coefficients, the default coefficients having a value of zero.

In an embodiment of the at least one processing device, wherein the creating of the candidate model based on the received measured data further includes creating the candidate model with default coefficients, the default coefficients having values equal to values of coefficients of a last learned candidate model or an enlisted model of one or more enlisted models.

In an embodiment of the at least one processing device, when the candidate model outperforms am enlisted model of one or more enlisted models and the current number of the enlisted models equals the preset number, the candidate model is made into a new enlisted model that replaces the enlisted model of the one or more enlisted models.

Embodiments of the present disclosure may provide a processing device for predicting standpipe pressure that includes at least one processor, and a memory connected with the at least one processor. The memory includes instructions for the at least one processor to perform operations. According to the operations, a Bayesian linear regressor is initialized. Priors for the Bayesian linear regressor are initialized based on previous drilling operations that use the same bottom hole assembly. Measurement data associated with drilling a well is received in real time. An online Bayesian linear regressor update is generated using QR decomposition for a model. Whether coefficients of the online Bayesian regressor update violate physical rules is determined. Responsive to determining that at least some of the coefficients violate the physical rules, the at least some of the coefficients are set to a respective default value that is either zero or a positive value. Coefficients and uncertainty are updated based on the online Bayesian linear regressor update or the setting of the at least some of the coefficients. The model then is visualized.

In an embodiment of the at least one processing device the operations further include applying an infinite impulse response filter to the received measurement data to be noise received measurement data.

In an embodiment of the processing device, the received measurement data includes standpipe pressure, flow rate, bit depth, surface weight on bit, and torque.

In an embodiment of the processing device, the QR decomposition extracts a column from an ill-positioned matrix to form a well-positioned sub-matrix, which is used to solve a matrix inversion equation with numerical stability.

In an embodiment of the processing advice, respective coefficients of the at least some of the coefficients conform to the physical rules when corresponding values of the respective coefficients fall within corresponding valid ranges of values.

Embodiments of the present disclosure may provide a method for predicting standpipe pressure. According to the method, a processing device initialized values of coefficients for a model. A processing device creates the model with the initialized coefficients as a candidate model. After fitting data for a period of time, the candidate model is promoted to an enlisted model. Until a number of enlisted models is a preset number, performing: receiving measured data during a next time interval; creating a candidate model based on the received measured data; dropping the candidate model when at least one coefficient of the candidate model violated a physical rule; and making the candidate model an enlisted model when all coefficients of the candidate model comply with the physical rule and a current number of enlisted models is less than the preset number. The standpipe pressure is predicted based on the enlisted models by applying a corresponding weight to a predicted standpipe pressure of each respective enlisted model to produce a respective weighted predicted standpipe pressure, the corresponding weight being based on an inverse of a variance or an inverse of a standard deviation of the respective enlisted model over a corresponding time interval. The respective weighted predicted standpipe pressures are added to produce a sum of the weighted predicted standpipe pressures based on the preset number of enlisted models. The sum of the weighted predicted standpipe pressures are divided by a sum of the weights to produce a predicted standpipe pressure based on the preset number of the listed models.

In an embodiment of the method, the creating of the candidate model based on the received measured data further includes creating the candidate model only when at least a preset period of time has passed since creation of a last model.

In an embodiment of the method in which the candidate model is created only when at least a preset period of time has passed since creation of a last model, the candidate model is created with default coefficients.

In an embodiment of the method in which the candidate model is created only when at least a preset period of time has passed since creation of a last model, the default coefficients have values equal to zero or have values equal to values of coefficients of a last learned candidate model or an enlisted model of one or more enlisted models.

In an embodiment of the method, when the candidate model outperforms an enlisted model of one or more enlisted models and the current number of the enlisted models equals the preset number, the candidate model is made into a new enlisted model that replaces the enlisted model of the one or more enlisted models.

Embodiments of the present disclosure may provide a non-transitory machine-readable storage medium having instructions stored thereon, which when executed by a processor of a processing device, configure the processing device to perform multiple operations. According to the operations, a Bayesian linear regressor is initialized. Priors for the Bayesian linear regressor are initialized based on previous drilling operations that use a same bottom hole assembly. Measurement data associated with drilling a well in real time is received. An online Bayesian linear regressor update is generated using QR decomposition for a model. Whether coefficients of the online Bayesian regressor update violate physical rules is determined. In response to determining that at least some of the coefficients violate the physical rules, the at least some of the coefficients are set to a respective default value that is either zero or a positive value. Coefficients and uncertainty are updated based on the online Bayesian linear regressor update or the setting of the at least some coefficients. The model then is visualized.

### DETAILED DESCRIPTION

Reference will now be made in detail to embodiments, examples of which are illustrated in the accompanying drawings and figures. In the following detailed description, numerous specific details are set forth in order to provide a thorough understanding of the invention. However, it will be apparent to one of ordinary skill in the art that the invention may be practiced without these specific details. In other instances, well-known methods, procedures, components, circuits, and networks have not been described in detail so as not to unnecessarily obscure aspects of the embodiments.

It will also be understood that, although the terms first, second, etc. may be used herein to describe various elements, these elements should not be limited by these terms. These terms are only used to distinguish one element from another. For example, a first object or step could be termed a second object or step, and, similarly, a second object or step could be termed a first object or step, without departing from the scope of the present disclosure. The first object or step, and the second object or step, are both, objects or steps, respectively, but they are not to be considered the same object or step.

The terminology used in the description herein is for the purpose of describing particular embodiments and is not intended to be limiting. As used in this description and the appended claims, the singular forms “a,” “an” and “the” are intended to include the plural forms as well, unless the context clearly indicates otherwise. It will also be understood that the term “and/or” as used herein refers to and encompasses any possible combinations of one or more of the associated listed items. It will be further understood that the terms “includes,” “including,” “comprises” and/or “comprising,” when used in this specification, specify the presence of stated features, integers, steps, operations, elements, and/or components, but do not preclude the presence or addition of one or more other features, integers, steps, operations, elements, components, and/or groups thereof. Further, as used herein, the term “if” may be construed to mean “when” or “upon” or “in response to determining” or “in response to detecting,” depending on the context.

Attention is now directed to processing procedures, methods, techniques, and workflows that are in accordance with some embodiments. Some operations in the processing procedures, methods, techniques, and workflows disclosed herein may be combined and/or the order of some operations may be changed.

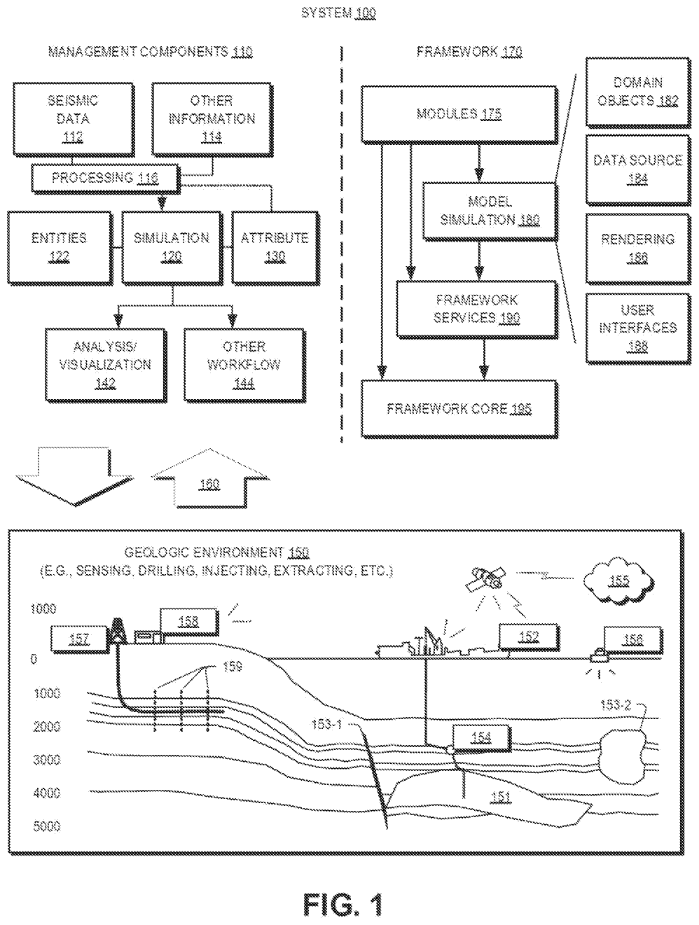

FIG. 1 illustrates an example of a system 100 that includes various management components 110 to manage various aspects of a geologic environment 150 (e.g., an environment that includes a sedimentary basin, a reservoir 151, one or more faults 153-1, one or more geobodies 153-2, etc.). For example, the management components 110 may allow for direct or indirect management of sensing, drilling, injecting, extracting, etc., with respect to the geologic environment 150. In turn, further information about the geologic environment 150 may become available as feedback 160 (e.g., optionally as input to one or more of the management components 110).

In the example of FIG. 1, the management components 110 include a seismic data component 112, an additional information component 114 (e.g., well/logging data), a processing component 116, a simulation component 120, an attribute component 130, an analysis/visualization component 142 and a workflow component 144. In operation, seismic data and other information provided per the components 112 and 114 may be input to the simulation component 120.

In an example embodiment, the simulation component 120 may rely on entities 122. Entities 122 may include earth entities or geological objects such as wells, surfaces, bodies, reservoirs, etc. In the system 100, the entities 122 can include virtual representations of actual physical entities that are reconstructed for purposes of simulation. The entities 122 may include entities based on data acquired via sensing, observation, etc. (e.g., the seismic data 112 and other information 114). An entity may be characterized by one or more properties (e.g., a geometrical pillar grid entity of an earth model may be characterized by a porosity property). Such properties may represent one or more measurements (e.g., acquired data), calculations, etc.

In an example embodiment, the simulation component 120 may operate in conjunction with a software framework such as an object-based framework. In such a framework, entities may include entities based on pre-defined classes to facilitate modeling and simulation. A commercially available example of an object-based framework is the MICROSOFT® .NET® framework (Redmond, Washington), which provides a set of extensible object classes. In the .NET® framework, an object class encapsulates a module of reusable code and associated data structures. Object classes can be used to instantiate object instances for use by a program, script, etc. For example, borehole classes may define objects for representing boreholes based on well data.

In the example of FIG. 1, the simulation component 120 may process information to conform to one or more attributes specified by the attribute component 130, which may include a library of attributes. Such processing may occur prior to input to the simulation component 120 (e.g., consider the processing component 116). As an example, the simulation component 120 may perform operations on input information based on one or more attributes specified by the attribute component 130. In an example embodiment, the simulation component 120 may construct one or more models of the geologic environment 150, which may be relied on to simulate behavior of the geologic environment 150 (e.g., responsive to one or more acts, whether natural or artificial). In the example of FIG. 1, the analysis/visualization component 142 may allow for interaction with a model or model-based results (e.g., simulation results, etc.). As an example, output from the simulation component 120 may be input to one or more other workflows, as indicated by a workflow component 144.

As an example, the simulation component 120 may include one or more features of a simulator such as the ECLIPSE™ reservoir simulator (Schlumberger Limited, Houston Texas), the INTERSECT™ reservoir simulator (Schlumberger Limited, Houston Texas), etc. As an example, a simulation component, a simulator, etc. may include features to implement one or more meshless techniques (e.g., to solve one or more equations, etc.). As an example, a reservoir or reservoirs may be simulated with respect to one or more enhanced recovery techniques (e.g., consider a thermal process such as SAGD, etc.).

In an example embodiment, the management components 110 may include features of a commercially available framework such as the PETREL® seismic to simulation software framework (Schlumberger Limited, Houston, Texas). The PETREL® framework provides components that allow for optimization of exploration and development operations. The PETREL® framework includes seismic to simulation software components that can output information for use in increasing reservoir performance, for example, by improving asset team productivity. Through use of such a framework, various professionals (e.g., geophysicists, geologists, and reservoir engineers) can develop collaborative workflows and integrate operations to streamline processes. Such a framework may be considered an application and may be considered a data-driven application (e.g., where data is input for purposes of modeling, simulating, etc.).

In an example embodiment, various aspects of the management components 110 may include add-ons or plug-ins that operate according to specifications of a framework environment. For example, a commercially available framework environment marketed as the OCEAN® framework environment (Schlumberger Limited, Houston, Texas) allows for integration of add-ons (or plug-ins) into a PETREL® framework workflow. The OCEAN® framework environment leverages .NET® tools (Microsoft Corporation, Redmond, Washington) and offers stable, user-friendly interfaces for efficient development. In an example embodiment, various components may be implemented as add-ons (or plug-ins) that conform to and operate according to specifications of a framework environment (e.g., according to application programming interface (API) specifications, etc.).

FIG. 1 also shows an example of a framework 170 that includes a model simulation layer 180 along with a framework services layer 190, a framework core layer 195 and a modules layer 175. The framework 170 may include the commercially available OCEAN® framework where the model simulation layer 180 is the commercially available PETREL® model-centric software package that hosts OCEAN® framework applications. In an example embodiment, the PETREL® software may be considered a data-driven application. The PETREL® software can include a framework for model building and visualization.

As an example, a framework may include features for implementing one or more mesh generation techniques. For example, a framework may include an input component for receipt of information from interpretation of seismic data, one or more attributes based at least in part on seismic data, log data, image data, etc. Such a framework may include a mesh generation component that processes input information, optionally in conjunction with other information, to generate a mesh.

In the example of FIG. 1, the model simulation layer 180 may provide domain objects 182, act as a data source 184, provide for rendering 186 and provide for various user interfaces 188. Rendering 186 may provide a graphical environment in which applications can display their data while the user interfaces 188 may provide a common look and feel for application user interface components.

As an example, the domain objects 182 can include entity objects, property objects and optionally other objects. Entity objects may be used to geometrically represent wells, surfaces, bodies, reservoirs, etc., while property objects may be used to provide property values as well as data versions and display parameters. For example, an entity object may represent a well where a property object provides log information as well as version information and display information (e.g., to display the well as part of a model).

In the example of FIG. 1, data may be stored in one or more data sources (or data stores, generally physical data storage devices), which may be at the same or different physical sites and accessible via one or more networks. The model simulation layer 180 may be configured to model projects. As such, a particular project may be stored where stored project information may include inputs, models, results and cases. Thus, upon completion of a modeling session, a user may store a project. At a later time, the project can be accessed and restored using the model simulation layer 180, which can recreate instances of the relevant domain objects.

In the example of FIG. 1, the geologic environment 150 may include layers (e.g., stratification) that include a reservoir 151 and one or more other features such as the fault 153-1, the geobody 153-2, etc. As an example, the geologic environment 150 may be outfitted with any of a variety of sensors, detectors, actuators, etc. For example, equipment 152 may include communication circuitry to receive and to transmit information with respect to one or more networks 155. Such information may include information associated with downhole equipment 154, which may be equipment to acquire information, to assist with resource recovery, etc. Other equipment 156 may be located remote from a well site and include sensing, detecting, emitting or other circuitry. Such equipment may include storage and communication circuitry to store and to communicate data, instructions, etc. As an example, one or more satellites may be provided for purposes of communications, data acquisition, etc. For example, FIG. 1 shows a satellite in communication with the network 155 that may be configured for communications, noting that the satellite may additionally or instead include circuitry for imagery (e.g., spatial, spectral, temporal, radiometric, etc.).

FIG. 1 also shows the geologic environment 150 as optionally including equipment 157 and 158 associated with a well that includes a substantially horizontal portion that may intersect with one or more fractures 159. For example, consider a well in a shale formation that may include natural fractures, artificial fractures (e.g., hydraulic fractures) or a combination of natural and artificial fractures. As an example, a well may be drilled for a reservoir that is laterally extensive. In such an example, lateral variations in properties, stresses, etc. may exist where an assessment of such variations may assist with planning, operations, etc. to develop a laterally extensive reservoir (e.g., via fracturing, injecting, extracting, etc.). As an example, the equipment 157 and/or 158 may include components, a system, systems, etc. for fracturing, seismic sensing, analysis of seismic data, assessment of one or more fractures, etc.

As mentioned, the system 100 may be used to perform one or more workflows. A workflow may be a process that includes a number of worksteps. A workstep may operate on data, for example, to create new data, to update existing data, etc. As an example, a may operate on one or more inputs and create one or more results, for example, based on one or more algorithms. As an example, a system may include a workflow editor for creation, editing, executing, etc. of a workflow. In such an example, the workflow editor may provide for selection of one or more pre-defined worksteps, one or more customized worksteps, etc. As an example, a workflow may be a workflow implementable in the PETREL® software, for example, that operates on seismic data, seismic attribute(s), etc. As an example, a workflow may be a process implementable in the OCEAN® framework. As an example, a workflow may include one or more worksteps that access a module such as a plug-in (e.g., external executable code, etc.).

Embodiments of the present disclosure may provide a method for abnormal pressure detection (APD) that includes an Online Bayesian Linear Regression method that includes QR decomposition. The method may improve aspects of time to starting computation (and to compute) and numerical stability.

Feeding the real-time streaming data (e.g., standpipe pressure, flowrate, torque and weight on bit), embodiments of the present disclosure can directly consume the data at the beginning of streaming. To update the designed model, a priori knowledge may be decomposed into a QR matrix. Then the new fed data will modify the decomposed QR matrix so that the QR matrix will be updated. Using the updated QR matrix, the method can give a new prediction on standpipe pressure.

The predicted standpipe pressure may be processed by the downstream APD workflow to generate alarm indicators, and the Low/High Standpipe Pressure may be adjusted accordingly.

Using Bayesian approaches in this context present several issues. When the data has high correlations, the coefficient update becomes trivial, which means the weight is distributed according to the scale of data. This introduces instability to predictions when data scale changes. Further, matrix inversion introduces runtime complexity and numerical instability. The direct matrix inversion operation may be of complexity O(N\hat{ }3) or O(N\hat{ }4). Using Gaussian Elimination to solve the matrix inversion complexity problem can lead to numerical instability. Both of these issues can harm APD workflows by slowing the computation time or decreasing the estimation precision. Additionally, there may not be a mechanism to ensure against violation of physical laws. Received data can contain unknown quality issues. The unqualified data may lead to an unreasonable estimated coefficient. The native Bayesian approach generally does not correct a physically meaningless coefficient.

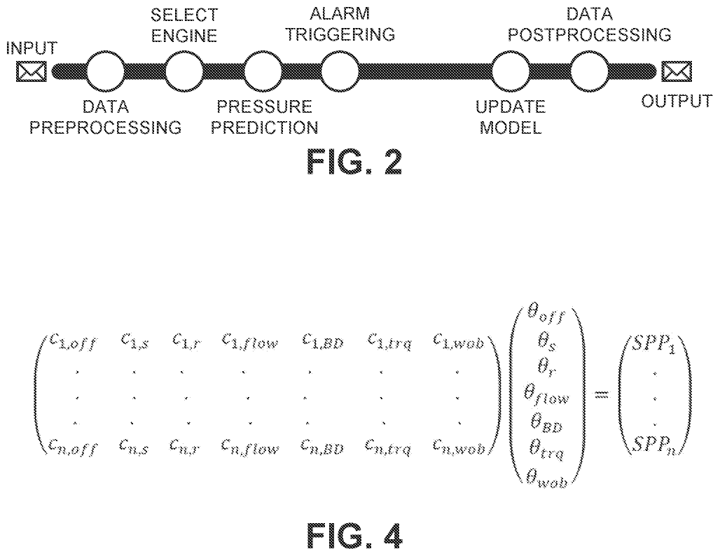

FIG. 2 illustrates a flowchart of a method for abnormal pressure detection in a standpipe, according to an embodiment. A Pressure Prediction workstep, as shown, may employ a single model for both rotating mode and sliding mode. Because there is a single model that is updated with time, potential issues with long durations between updates of the model are avoided, as discussed above. In some embodiments, a following relationship may be assumed:

SPP=C₀*ε₀+a*Q²+b*BD*Q²+c*Wob*ε_{W}+d*Trq*εₜ+Cᵣ*εᵣ₊+Cₛ*εₛ, where
SPP: Standpipe pressure.
C₀: Constant pressure for off bottom.
Q²: Flowrate squared.
BD*Q²: Multiplication of bit depth and flowrate squared.
Wob: Weight on Bit. Only surface Wob is used in abnormal pressure detection.
Trq: Torque.
Cᵣ: Constant pressure for rotating mode.
Cₛ: Constant pressure for sliding mode.
a, b, c, d: Coefficients for corresponding terms.
ε_{W}, εₜ: 0/1 indicators, respectively, for weight on bit (Wob), and torque (Trq).
ε₀, εᵣ, εₛ: 0/1 indicators, respectively, for off bottom, rotating and sliding.
   Mapping this relationship with Y=X^{t}*θ+e, where Y is SPP, θ is [C₀, a, b, c, d, Cᵣ, Cₛ], X^{t} is a measurement matrix, and e is assumed to be white noise.

In some embodiments of the method, instead of using a calibration point to fit the model, the model is fit to a full set of data received. Thus, the model may begin functioning when the data is received, e.g., without finding a calibration point first. Further, a pressure profile may be given directly by the model instead of by a Gaussian Process, which may avoid risks of solutions that violate physics.

Additionally, methods may use QR decomposition to transform involved matrix computation in the Bayesian linear regression process. Using the QR decomposition, a matrix inversion computation may be sped up. Further, when there is an ill-positioned matrix (whose conditioning number (ratio between a largest and a smallest eigenvector of the matrix) is generally high), QR decomposition can extract a column to form a well-positioned sub-matrix, which can be used to solve the matrix inversion equation with numerical stability.

Embodiments may also provide a physicality check integrated with QR decomposition. When the fitted model coefficient violates a physical law constraint, the coefficient can be reinitialized and the QR matrix can be corrected correspondingly. A model coefficient may be determined to violate a physical law if the coefficient is outside of a given range. The QR decomposition is advantageous in that a partially correct model may be used instead of dropping the complete model.

In summary, embodiments of the present method may ensure model monotonicity by applying constraints on model coefficients. Further, flowrate, bit depth, torque, and weight on bit may be used as model parameters. There may not be any specific calibration points, but calibration may occur continuously while pumping and not in a transient stage. Further, a small learning rate may be used, and can adapt to context changes such as mud change, to update the model in alarm conditions.

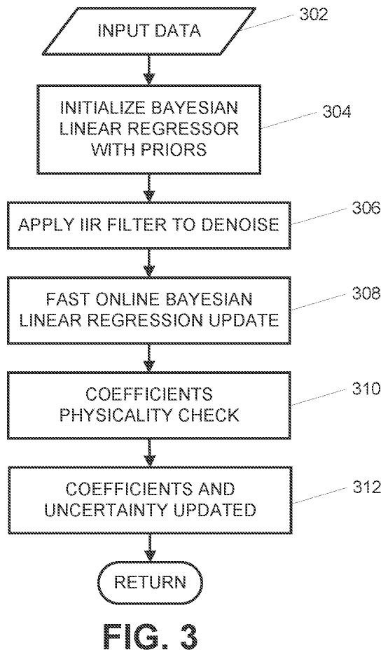

FIG. 3 illustrates a more detailed flowchart of an embodiment of the method, according to an embodiment. The method may begin with receiving input data such as, for example, bit depth, torque, weight on bit, flowrate, etc. (act 302). The method, as shown, may include initialization of a Bayesian Linear Regressor with a priori information (act 304). If in the well drilling operation, the current bottom hole assembly (BHA) run is not an initial run, then the model coefficient of the previous BHA run may become the a priori coefficient for the current new BHA run. For the initialization of the covariance matrix, when the matrix has been specified, the covariance matrix may be decomposed using Cholesky decomposition. An upper triangle matrix and a derived target vector may be stored as the R matrix and the Q.Y vector respectively. Accordingly, starting from the second BHA run drilling operation, this priori is initialized in an informative way (coefficients and covariance are not trivial), adopting information (matrix R) from a previous BHA run.

The method may also include applying an infinite impulse response (IIR) filter to denoise (act 306). Any data filtration technique may be used to remove or otherwise attenuate noise.

Next, the method may include applying a Fast Online Bayesian Linear Regressor Update (act 308). The new received data (X, Y pair, see FIG. 4 for the APD model) may be appended into the original R matrix and Q.Y vector. Using the isometric transformation, the data pair (X,Y) may by nullified and the R matrix and Q.Y vector may be updated at the same time. To update the model, an equation Rθ=Q.Y may be solved. Solving of the linear equation system may be based on selected columns, e.g., a sub-matrix whose conditioning number is acceptable to avoid ill-positioned matrix issues. Using the selected columns to solve the linear equation system can ensure numerical stability because the condition number is small. Accordingly, a new numerically stable computation accelerates the regression and enables a possibility of a physicality check.

Next, the method may include a coefficients physicality check (act 310). Because of potential unknown data quality issues, some coefficients could be fitted such that laws of physics are violated (e.g., coefficients are outside a valid range). In this situation, the coefficients may be reinitialized with a default value. Then the stored R matrix and the stored Q.Y vector may be corrected by removing a contribution of an influence of the corrected coefficients columns. This correction is achieved by performing a new fitting: setting the coefficient to be corrected to 0 and then selecting a sub-matrix of R and Q.Y, such that a column and a row that corresponds to the corrected coefficient are not included. The sub-matrix R and Q.Y are then updated. Thus, the coefficients may be corrected to align with physical reality.

The method may also include a coefficients and uncertainty update (act 312). The updated posteriori coefficients, covariance (or precision, or equivalent semi-precision) matrix, posteriori R matrix and Q.Y vector may be updated as the priori knowledge to the next streaming computation.

In some embodiments, another initialization process can be used for the regressor (e.g., using historical data, or using a previously trained model's coefficients). An extension of the APD model (e.g., using a lower/higher dimension models or pass data into another space by applying a kernel transformation) may also be employed. A replacement of Bayesian logic by Kalman Filter related logic may be used. Bayesian linear regression for coefficients may be similar to Kalman Filter coefficients updates and Bayesian linear regression can estimate the measurement noise level whereas the Kalman filter may not. Another matrix decomposition or isometric transformation may also be used to create or update the decomposed covariance matrix and data pair.

Further, another way to consume the predicted standpipe pressure data and to trigger the alarm without changing the core modeling process may be employed. In this situation, the data consumed by the model to derive the output has been changed, and may lead to a change on the output, but may not change the model itself.

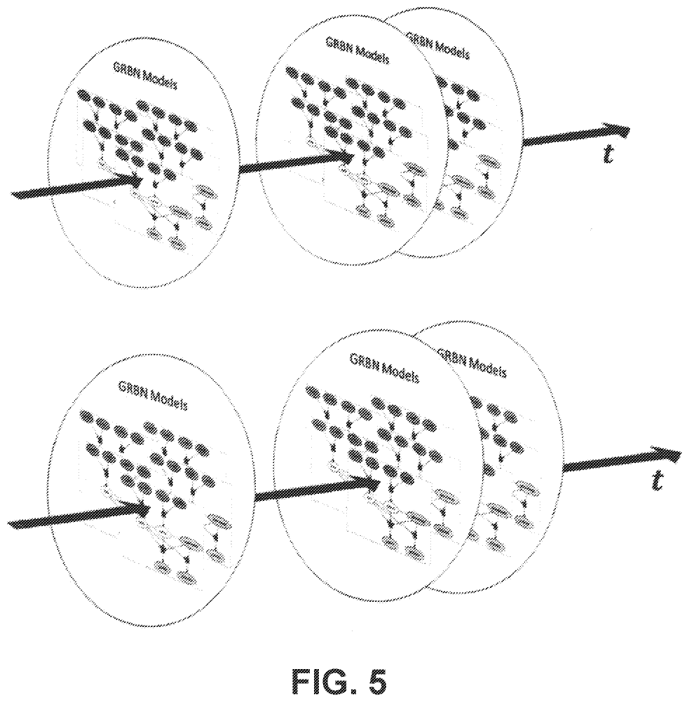

FIG. 5 illustrates a schematization of one embodiment of a GRBN workflow. In FIG. 5, with the time axis, data may be sent to the GRBN models in real-time. As used herein, ‘real-time’ may refer to instantaneous, but can also refer to slower data. Given the nature of data being collected at a drilling operation, there may be delays in transmission and/or receipt of certain categories of data. As such, real-time can also refer to data received sufficiently soon after generation that the system can use data received during operations to predict current and future parameters and events for the wellsite operations.

As noted above, the approach may use a GRBN methodology to achieve the ability of abnormal pressure detection in real time during drilling performance. The real time data may be collected and processed. In one embodiment, the abnormal pressure detection system operates on a computing system at the rig; in another embodiment, the data is sent over a network to a series of remote computers which execute the functions to detect abnormal pressure conditions. In such an embodiment, the remote computers may make the information and notifications available over a browser, through notifications, or other means. Thus, in one embodiment, the abnormal pressure detection system is an installed, on-premises software application deployed on the rig and providing alerts and alarms to personnel on the rig. In another embodiment, the abnormal pressure detection system is a web-based application that is accessible using an Internet browser. The system may also be realized as a hybrid on-premises/cloud solution to enable both rig site operations and personnel and remote monitoring operations monitoring workflows.

The data from the rig may be pre-processed and fed into GRBN models. The data may include standpipe pressure, flowrate, surface torque, weight on bit, and others. The measured standpipe pressure may come from resource data and a predicted standpipe pressure may be predicted by the GRBN models. These two standpipe pressure values may be compared and indicators for low standpipe pressure and high standpipe pressure may be calculated. Alarms for low and high values may be calculated and sent to relevant personnel.

The alarms may be displayed on a graphical user interface (GUI) of an application. In another embodiment, the alarms may be pushed or transmitted to mobile devices of associated personnel. A combination of the above approaches may also be used.

A recursive Bayesian network may configured to start calculations as long as valid streaming data has been fed into the model. One potential benefit of such an approach is that there may be no calibration period. Using a group of recursive Bayesian networks may facilitate evolving the models by replacing models. At the beginning, if the data has a quality issue which is later correct, the GRBN may replace the bad fitted models created at the beginning with the well-fitted models created afterwards. The GRBN may also be equipped with a model check process using physical meaning to help prune and handle badly fitted models. GRBN may also have the ability to estimate the measured standpipe pressure uncertainty. Thus, it may provide adjusted prediction uncertainty with an adaptive lower bound.

An algorithm may generate an incorrect model due to data quality issues. In such an instance, the predicted standpipe pressure may fit the measured standpipe pressure at the beginning of the job, but deviate significantly afterwards.

In other instances, there may be a significant drop in measured standpipe pressure at the beginning of the job. Where the model is calibrated to the higher standpipe pressure values, the model may result in too many alarms being raised during execution. A GRBN approach may initially raise the alarms, but also learn from the trends in the data to make more reasonable decisions about when to raise the alarm as the job progresses.

A GRBN may provide the ability to estimate the measured standpipe pressure uncertainty for different data. Noisy data may result in a high level of standpipe pressure uncertainly, which may lead to large prediction uncertainty as well. Precise data may result in high levels of measured standpipe pressure precision, leading to increased prediction precision.

In one embodiment, a method for predicting abnormal pressure conditions and events involves data pre-processing. Streaming data may be cleaned, consolidated and prepared for use in machine learning workflows.

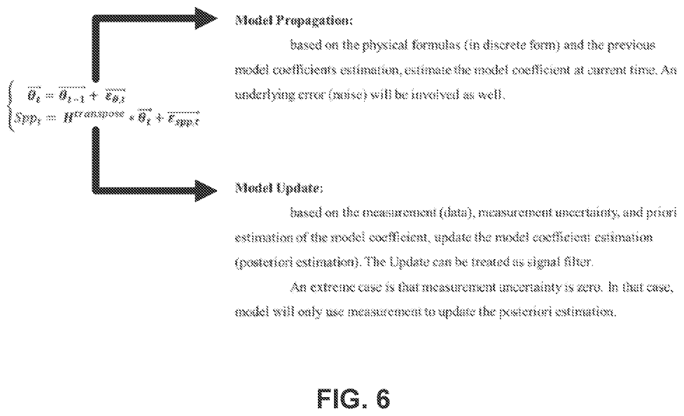

FIG. 6 illustrates an embodiment of an RBN consuming streaming data. In one embodiment, at each time that streaming data is fed, the RBN propagates the stored model (model propagation). Having propagated the model, and before the update, the RBN may be configured to predict the standpipe pressure and give the result in formation of distribution. Subsequently, the RBN may update the model coefficients (model update). In one embodiment, in the RBN model, both model parameters θ and the measured standpipe pressure uncertainty εₛₚₚ (where spp is standpipe pressure) are estimated in the model update step.

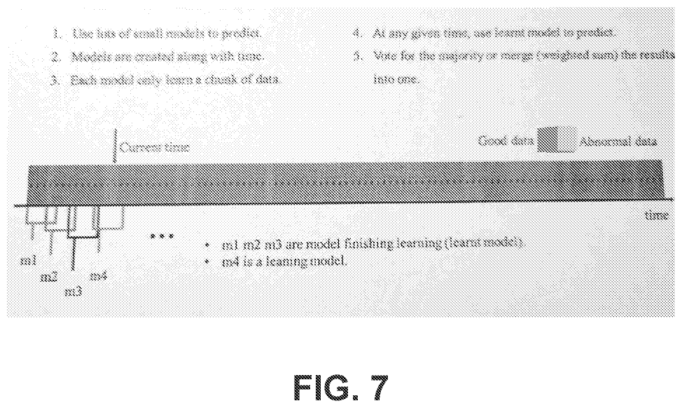

FIG. 7 illustrates one embodiment of an approach to ensemble learning. In one embodiment, a recursive version is used. In the recursive (real-time) scenario, the grouping conceptually illustrated in FIG. 7 comprises five steps. In one embodiment, which model to use is an indifferent question in an aspect of the grouping. The RBN model may be engaged in one embodiment; however, on other embodiments, any model with the same functionality may be used. In one embodiment, for abnormal pressure detection, the step 5 in the figure will merge a weighted sum on distribution. Weights may be calculated based on an inverse of a variance or a standard deviation. In one embodiment, a model physical meaning checking step is implemented after a new model has been created. Based on the result of the check, the model may be kept or dropped.

In one embodiment, as time passes, an increasing number of models will have been created and added to the ensemble. The approach may involve determining which models to keep and which models to remove from the grouping. In one embodiment, an evolutionary approach is designed for the grouping in order to keep updated models that are appropriate and in order to prune redundant models.

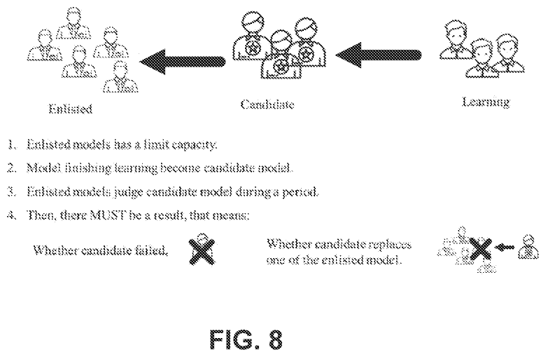

FIG. 8 illustrates one embodiment of an evolutionary mechanism. In the mechanism, a limited number of models are kept as enlisted models. The limited number may be different in various embodiments. For example, the limited number may be 5, 10, or another suitable number. When a new model is trained, the system may be configured to produce a result schematized as the item 4 in FIG. 8. Thus, if a candidate model failed, the candidate model is dropped. Otherwise, if the candidate model produces better results that an enlisted model, the candidate model replaces the enlisted model.

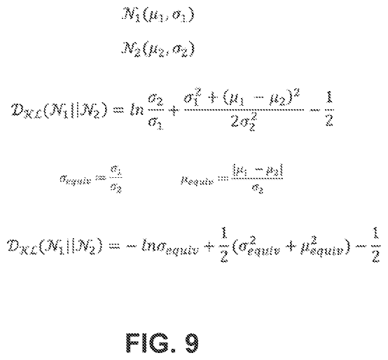

In one embodiment, Kullback-Leibler divergence is used to select the model as illustrated in FIG. 9. In an instance where there are two results Kullback-Leibler divergence may be used to calculate the distance between the two distributions.

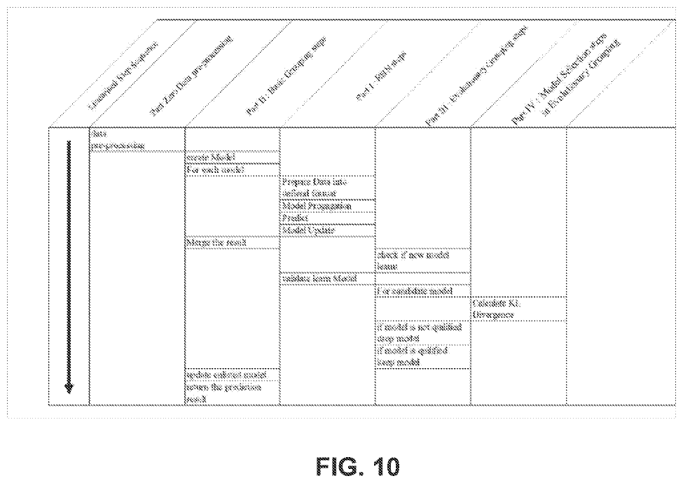

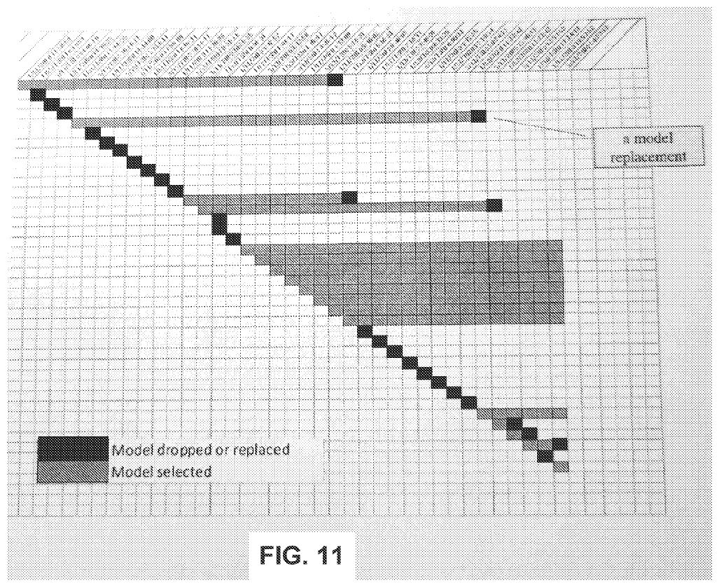

FIG. 10 illustrates one embodiment of an approach to a GRBN system operating on streaming data as described above. Other variations may also be implemented. According to FIG. 10, data is pre-processed. A candidate model is then created. The data is prepared into a defined format, the model is propagated, a pressure prediction is made based on the model, and the model is then updated. A check is performed to determine if the model is learned. To determine whether the model is learned, a fed data time index is checked against the fed data time index+candidate model create time index+learning time period. If the fed data is late, then according to the ending time index the model is considered learned. Otherwise, the candidate model continues fitting the fed data. If the model is learned, the model may be validated by calculating a Kullback-Liebler divergence of the two models. If the model is not qualified, the model is dropped. Otherwise, the model is kept. The enlisted models then may be updated and the prediction result may be returned.

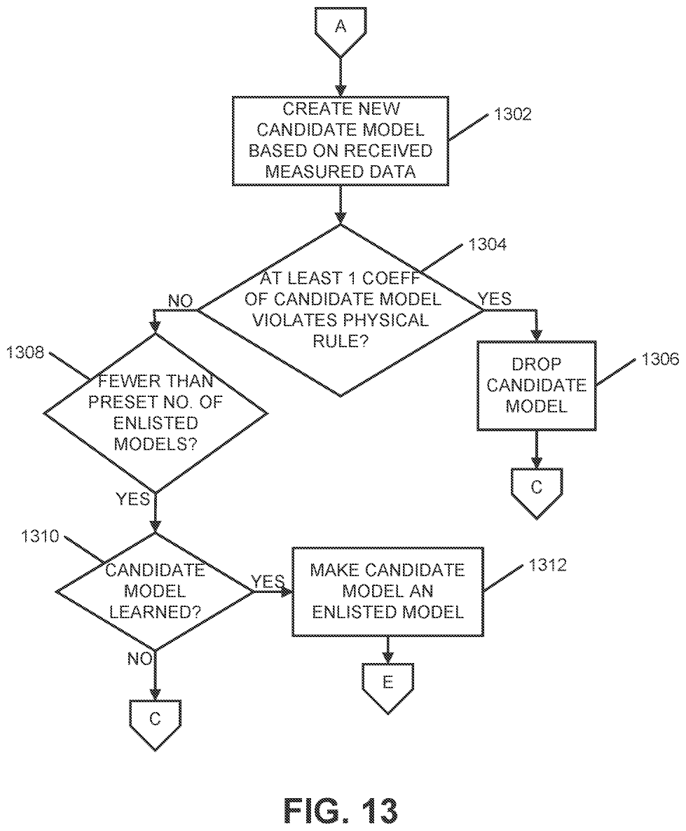

FIG. 11 illustrates one embodiment of an approach showing how models may be kept (enlisted models) in groupings as the system evolves. In FIG. 13, the blocks at the first column in a row represents a trained model. Gray blocks represent that the model is kept and used. Black blocks represent models that are dropped from the group and not actively used.

In one embodiment, this results in three typical scenarios. In one, the rows start with a gray block and end with a black block. This represents a model that is selected and kept since it has been trained, but later a better model replaces the model. A row may start with a black block and no subsequent blocks. This represents an instance where the model is directly dropped once it has been trained; for example, it may have failed to perform adequately to join the grouping in the first place. Third, a row may start with a gray block and be followed with gray blocks. This represents models that have been trained and continue to be used for the streaming data computation.

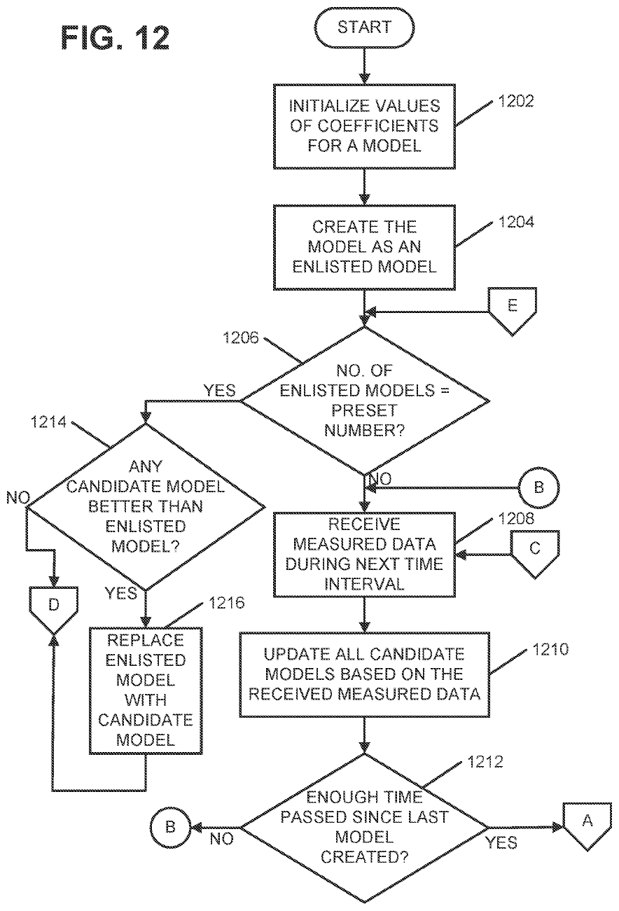

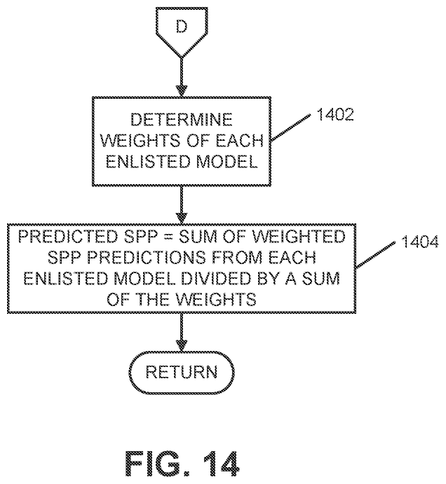

FIGS. 12-14 are flowcharts that help explain processing in an embodiment. The process may begin by initializing values of coefficients for a first model (act 1202), which is created as an enlisted model (act 1204). Next, a determination is made regarding whether a number of enlisted models is equal to a preset number of models (act 1206). The preset number of models may be 5, 10, or another suitable number of models.

If, during act 1206, the number of enlisted models is determined not to be equal to the preset number of models, then at a next time interval measured data is received (act 1208). Using the received measured data, all candidate models are updated (act 1210). A determination then may be made regarding whether enough time has passed since a last model was created (act 1212).

If, during act 1212 enough time is determined not to have passed since the last model was created, then acts 1208-1210 may again be performed. Otherwise, a new candidate model is created based on the received measured data (act 1302). A determination may be made regarding whether at least one coefficient of the new candidate model violates a physical rule (act 1304). According to the physical rule, each coefficient is to be within a respective valid range. In some embodiments, the physical rule requires coefficients to have a positive value. If, during act 1304, at least one coefficient of the new candidate model violates the physical rule, then the new candidate model is dropped and acts 1210-1212 may again be performed. Otherwise, if, during act 1304, none of the coefficients of the new candidate model are determined to violate the physical rule, then a determination is made regarding whether fewer than the preset number of enlisted models are being used.

If, during act 1308, fewer than the preset number of enlisted models is determined to be used then a determination may be made regarding whether any of the candidate models had been learned. If a candidate model has been determined to have been learned, then the candidate model becomes a new enlisted model and acts 1206-1212 may again be performed.

If, during act 1310, none of the candidate models have been determined to have been learned, then acts 1208-1212 may again be performed.

If, during act 1308, a determination is made that there are not fewer than the preset number of enlisted models, then act 1214 may be performed to determine whether any candidate model is better than an any enlisted model.

If, during act 1206, the number of enlisted models is determined to be equal to the preset number, then act 1214 may be performed to determine whether any candidate model is better than any enlisted model. If a candidate model is determined to be better than any enlisted model, then the enlisted model is replaced with the candidate model (act 1216).

After performing act 1214 and determining that none of the candidate models is better than any of the enlisted models, or after performing act 1216, weights are determined for each enlisted model (act 1402). In one embodiment, the weights may be an inverse of a variance of a model. In another embodiment, the weights may be an inverse of a standard deviation of a model. Thus, for example, if the weight is based on the variance and the variance is determined to be equal to 0.2, the weight is determined to be 5. If the weight is based on the standard deviation, which is determined to have a value of 0.325, then the weight is determined to be about 3.08.

The predicted standpipe pressure then may be determined as a sum of the weighted

$$SPP = \frac{{\sum }_{i = 1}^{n} ( {w}_{i} * {SPP}_{i} )}{{\sum }_{i = 1}^{n} {w}_{i}} ,$$

predicted pressures divided by a sum of the weights (act 1404), where i refers to a model number, wᵢ is a weight corresponding to the i^{th} model, and SPPᵢ is a predicted SPP according to the i^{th} model.

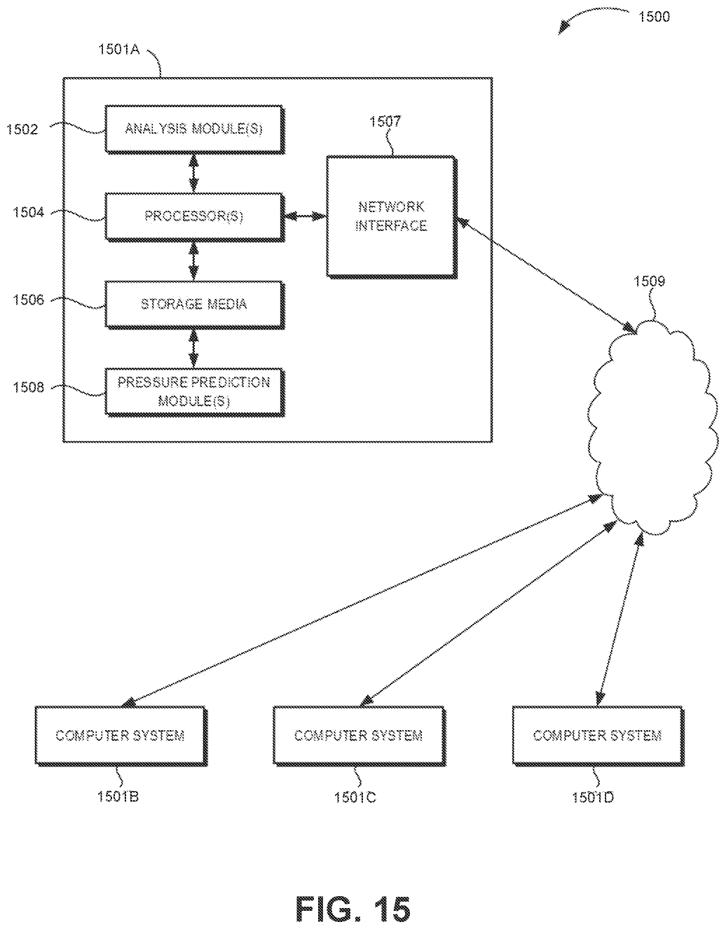

In some embodiments, the methods of the present disclosure may be executed by a computing system. FIG. 15 illustrates an example of such a computing system 500, in accordance with some embodiments. The computing system 1500 may include a computer or computer system 1501A, which may be an individual computer system 1501A or an arrangement of distributed computer systems. The computer system 1501A includes one or more analysis modules 1502 that are configured to perform various tasks according to some embodiments, such as one or more methods disclosed herein. To perform these various tasks, the analysis module 1502 executes independently, or in coordination with, one or more processors 1504, which is (or are) connected to one or more storage media 1506. The processor(s) 1504 is (or are) also connected to a network interface 1507 to allow the computer system 1501A to communicate over a data network 1509 with one or more additional computer systems and/or computing systems, such as 1501B, 1501C, and/or 1501D (note that computer systems 1501B, 1501C and/or 1501D may or may not share the same architecture as computer system 1501A, and may be located in different physical locations, e.g., computer systems 1501A and 1501B may be located in a processing facility, while in communication with one or more computer systems such as 1501C and/or 1501D that are located in one or more data centers, and/or located in varying countries on different continents).

A processor may include a microprocessor, microcontroller, processor module or sub-system, programmable integrated circuit, programmable gate array, or another control or computing device.

The storage media 1506 may be implemented as one or more computer-readable or machine-readable storage media. Note that while in the example embodiment of FIG. 15 storage media 1506 is depicted as within computer system 1501A, in some embodiments, storage media 1506 may be distributed within and/or across multiple internal and/or external enclosures of computing system 1501A and/or additional computing systems. Storage media 1506 may include one or more different forms of memory including semiconductor memory devices such as dynamic or static random access memories (DRAMs or SRAMs), erasable and programmable read-only memories (EPROMs), electrically erasable and programmable read-only memories (EEPROMs) and flash memories, magnetic disks such as fixed, floppy and removable disks, other magnetic media including tape, optical media such as compact disks (CDs) or digital video disks (DVDs), BLURAY® disks, or other types of optical storage, or other types of storage devices. Note that the instructions discussed above may be provided on one computer-readable or machine-readable storage medium, or may be provided on multiple computer-readable or machine-readable storage media distributed in a large system having possibly plural nodes. Such computer-readable or machine-readable storage medium or media is (are) considered to be part of an article (or article of manufacture). An article or article of manufacture may refer to any manufactured single component or multiple components. The storage medium or media may be located either in the machine running the machine-readable instructions, or located at a remote site from which machine-readable instructions may be downloaded over a network for execution.

In some embodiments, computing system 1500 contains one or more pressure prediction module(s) 1508. In the example of computing system 1500, computer system 1501A includes the pressure prediction module 1508. In some embodiments, a single pressure prediction module may be used to perform some aspects of one or more embodiments of the methods disclosed herein. In other embodiments, a plurality of pressure prediction modules may be used to perform some aspects of methods herein.

It should be appreciated that computing system 1500 is merely one example of a computing system, and that computing system 1500 may have more or fewer components than shown, may combine additional components not depicted in the example embodiment of FIG. 15, and/or computing system 1500 may have a different configuration or arrangement of the components depicted in FIG. 15. The various components shown in FIG. 15 may be implemented in hardware, software, or a combination of both hardware and software, including one or more signal processing and/or application specific integrated circuits.

Further, the steps in the processing methods described herein may be implemented by running one or more functional modules in information processing apparatus such as general purpose processors or application specific chips, such as ASICs, FPGAs, PLDs, or other appropriate devices. These modules, combinations of these modules, and/or their combination with general hardware are included within the scope of the present disclosure.

Computational interpretations, models, and/or other interpretation aids may be refined in an iterative fashion; this concept is applicable to the methods discussed herein. This may include use of feedback loops executed on an algorithmic basis, such as at a computing device (e.g., computing system 1500, FIG. 15), and/or through manual control by a user who may make determinations regarding whether a given step, action, template, model, or set of curves has become sufficiently accurate for the evaluation of the sub-surface three-dimensional geologic formation under consideration.

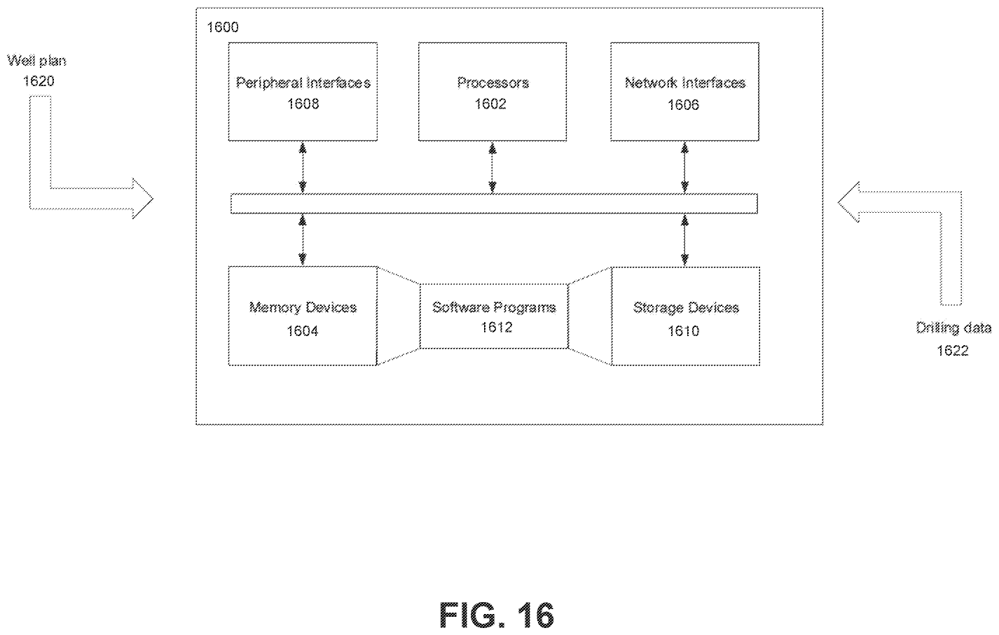

FIG. 16 illustrates a schematic view of a computing or processor system 1600 according to another embodiment. The processor 1600 may include one or more processors 1602 of the varying core configurations (including multiple cores) and clock frequencies. The one or more processors 1602 may be operable to execute instructions, apply logic, etc. It will be appreciated that these functions may be provided by multiple processors or multiple cores on a single chip operating in parallel and/or communicably linked together. In at least one embodiment, the one or more processors 602 may be or include one or more GPUs.

The processor system 1600 may also include a memory system, which may be or may include one or more memory devices and/or computer-readable media 1604 of varying physical dimensions, accessibility, storage capacities, etc. such as flash drives, hard drives, disks, random access memory, etc., for storing data, such as images, files, and program instructions for execution by the processor 1602. In an embodiment, the computer-readable media 1604 may store instructions that, when executed by the processor 1602, are configured to cause the processor system 1600 to perform operations. For example, execution of such instructions may cause the processor system 1600 to implement one or more portions and/or embodiments of the method(s) described above.

The processor system 1600 may also include one or more network interfaces 1606. The network interfaces 1606 may include any hardware, applications, and/or other software. Accordingly, the network interfaces 1606 may include Ethernet adapters, wireless transceivers, PCI interfaces, and/or serial network components, for communicating over wired or wireless media using protocols, such as Ethernet, wireless Ethernet, etc.

As an example, the processor system 1600 may be a mobile device that includes one or more network interfaces to communicate information. For example, a mobile device may include a wireless network interface (e.g., operable via one or more IEEE 802.11 protocols, ETSI GSM, BLUETOOTH®, satellite, etc.). As an example, a mobile device may include components such as a main processor, memory, a display, display graphics circuitry (e.g., optionally including touch and gesture circuitry), a SIM slot, audio/video circuitry, motion processing circuitry (e.g., accelerometer, gyroscope), wireless LAN circuitry, smart card circuitry, transmitter circuitry, GPS circuitry, and a battery. As an example, a mobile device may be configured as a cell phone, a tablet, etc. As an example, a method may be implemented (e.g., wholly or in part) using a mobile device. As an example, a system may include one or more mobile devices.

The processor system 1600 may further include one or more peripheral interfaces 608, for communication with a display, projector, keyboards, mice, touchpads, sensors, other types of input and/or output peripherals, and/or the like. In some implementations, the components of processor system 1600 need not be enclosed within a single enclosure or even located in close proximity to one another, but in other implementations, the components and/or others may be provided in a single enclosure. As an example, a system may be a distributed environment, for example, a so-called “cloud” environment where various devices, components, etc. interact for purposes of data storage, communications, computing, etc. As an example, a method may be implemented in a distributed environment (e.g., wholly or in part as a cloud-based service).

As an example, information may be input from a display (e.g., a touchscreen), output to a display or both. As an example, information may be output to a projector, a laser device, a printer, etc. such that the information may be viewed. As an example, information may be output stereographically or holographically. As to a printer, consider a 2D or a 3D printer. As an example, a 3D printer may include one or more substances that can be output to construct a 3D object. For example, data may be provided to a 3D printer to construct a 3D representation of a subterranean formation. As an example, layers may be constructed in 3D (e.g., horizons, etc.), geobodies constructed in 3D, etc. As an example, holes, fractures, etc., may be constructed in 3D (e.g., as positive structures, as negative structures, etc.).

The memory device 1604 may be physically or logically arranged or configured to store data on one or more storage devices 1610. The storage device 1610 may include one or more file systems or databases in any suitable format. The storage device 1610 may also include one or more software programs 1612, which may contain interpretable or executable instructions for performing one or more of the disclosed processes. When requested by the processor 1602, one or more of the software programs 1612, or a portion thereof, may be loaded from the storage devices 1610 to the memory devices 1604 for execution by the processor 1602.

Those skilled in the art will appreciate that the above-described componentry is merely one example of a hardware configuration, as the processor system 1600 may include any type of hardware components, including any accompanying firmware or software, for performing the disclosed implementations. The processor system 1600 may also be implemented in part or in whole by electronic circuit components or processors, such as application-specific integrated circuits (ASICs) or field-programmable gate arrays (FPGAs).

The processor system 1600 may be configured to receive a directional drilling well plan 620. A well plan is to the description of the proposed wellbore to be used by the drilling team in drilling the well. The well plan typically includes information about the shape, orientation, depth, completion, and evaluation along with information about the equipment to be used, actions to be taken at different points in the well construction process, and other information the team planning the well believes will be relevant/helpful to the team drilling the well. A directional drilling well plan will also include information about how to steer and manage the direction of the well.

The processor system 1600 may be configured to receive drilling data 1622. The drilling data 1622 may include data collected by one or more sensors associated with surface equipment or with downhole equipment. The drilling data 1622 may include information such as data relating to a position of a BHA (such as survey data or continuous position data), drilling parameters (such as weight on bit (WOB), rate of penetration (ROP), torque, or others), text information entered by individuals working at the wellsite, or other data collected during the construction of the well.

In one embodiment, the processor system 1600 is part of a rig control system (RCS) for the rig. In another embodiment, the processor system 1600 is a separately installed computing unit including a display that is installed at the rig site and receives data from the RCS. In such an embodiment, the software on the processor system 1600 may be installed on the computing unit, brought to the wellsite, and installed and communicatively connected to the rig control system in preparation for constructing the well or a portion thereof.

In another embodiment, the processor system 1600 may be at a location remote from the wellsite and receives the drilling data 1622 over a communications medium using a protocol such as well-site information transfer specification or standard (WITS) and markup language (WITSML). In such an embodiment, the software on the processor system 1600 may be a web-native application that is accessed by users using a web browser. In such an embodiment, the processor system 1600 may be remote from the wellsite where the well is being constructed, and the user may be at the wellsite or at a location remote from the wellsite.

The foregoing description, for purpose of explanation, has been described with reference to specific embodiments. However, the illustrative discussions above are not intended to be exhaustive or limiting to the precise forms disclosed. Many modifications and variations are possible in view of the above teachings. Moreover, the order in which the elements of the methods described herein are illustrated and described may be re-arranged, and/or two or more elements may occur simultaneously. The embodiments were chosen and described in order to best explain the principles of the disclosure and its practical applications, to thereby enable others skilled in the art to best utilize the disclosed embodiments and various embodiments with various modifications as are suited to the particular use contemplated.

What is claimed is:

1. A method for predicting standpipe pressure, the method comprising:
initializing a Bayesian linear regressor, wherein priors for the Bayesian linear regressor are initialized based on previous drilling operations that used a similar bottom hole assembly;
receiving measurement data associated with drilling a well in real time;
generating an online Bayesian linear regressor update using QR decomposition for a model;
verifying that all coefficients satisfy physical rules and outputting uncertainties of the coefficients based on at least one of the online Bayesian linear regressor update and the setting of the at least some of the coefficients; and
visualizing the model.

2. The method of claim 1, further comprising:
determining that at least some coefficients of the online Bayesian regressor update violate physical rules;
in response to the determining that at least some of the coefficients violate the physical rules, setting the at least some of the coefficients to a respective default value that is either zero r a positive value; and
updating coefficients and uncertainties of the coefficients based at least on one of the online Bayesian linear regressor update and the setting of the at least some of the coefficients.

3. The method of claim 1, further comprising:
denoising the received measurement data by applying an infinite impulse response filter thereto.

4. The method of claim 1, wherein the received measurement data comprises:
standpipe pressure, flow rate, bit depth, surface weight on bit, and torque.

5. The method of claim 1, wherein the QR decomposition solves a matrix inversion using a sub-matrix.

6. The method of claim 2, wherein respective coefficients of the at least some of the coefficients conform to the physical rules when corresponding values of the respective coefficients fall within corresponding valid ranges of values.

7. At least one processing device for predicting a standpipe pressure, each of the at least one processing device comprising:
at least one processor; and
a memory connected with the at least one processor, wherein the memory includes instructions for the at least one processor to perform a plurality of operations comprising:
initializing values of coefficients for a model;
creating the model with the initialized coefficients as an enlisted model;
repeating until a number of enlisted models is a preset number:
receiving measured data during a next time internal;
updating all candidate models based on the received measured data;
creating a candidate model based on the received measured data;
dropping the candidate model when at least one coefficient of the candidate model violates a physical rule; and
making the candidate model an enlisted model after the candidate model is learned, all coefficients of the candidate model comply with the physical rule and a current number of enlisted models is less than the preset number;
predicting the standpipe pressure based on the enlisted models by applying a corresponding weight to a predicted standpipe pressure of each respective enlisted model to produce a respective weighted predicted standpipe pressure, the corresponding weight being based on an inverse of one of a variance and a standard deviation of the respective enlisted model over a corresponding time interval;
adding the respective weighted predicted standpipe pressures to produce a sum of the weighted pressures; and
dividing the sum of the weighted pressures by a sum of the weights to produce a predicted standpipe pressure based on the preset number of the enlisted models.

8. The at least one processing device of claim 7, wherein the creating the candidate model based on the received measured data further comprises:
creating the candidate model only when at least a preset period of time has passed since creation of a last model.

9. The at least one processing device of claim 8, wherein the creating the candidate model based on the received measured data further comprises:
creating the candidate model with default coefficients.

10. The at least one processing device of claim 9, wherein the default coefficients have a value of zero.

11. The at least one processing device of claim 9, wherein the default coefficients have values equal to values of coefficients of one of a last learned candidate model and an enlisted model of one or more enlisted models.

12. The at least one processing device of claim 7, wherein the repeating further comprises:
when the candidate model outperforms an enlisted model of one or more enlisted models and the current number of the enlisted models equals the preset number, making the candidate model a new enlisted model that replaces the enlisted model of the one or more enlisted models.

13. A processing device for predicting standpipe pressure comprising:
at least one processor; and
a memory connected with the at least one processor, wherein the memory includes instructions for the at least one processor to perform a plurality of operations comprising:
initializing a Bayesian linear regressor, wherein priors for the Bayesian linear regressor are initialized based on previous drilling operations that used a similar bottom hole assembly;
receiving measurement data associated with drilling a well in real time;
generating an online Bayesian linear regressor update using QR decomposition for a model;
determining whether coefficients of the online Bayesian regressor update violate physical rules;
in response to determining that at least some of the coefficients violate the physical rules, setting the at least some of the coefficients to a respective default value that is either zero or a positive value;
updating coefficients and uncertainty based on at least one of the online Bayesian linear regressor update and the setting of the at least some of the coefficients; and
visualizing the model.

14. The processing device of claim 13, wherein the plurality of operations further comprise:
applying an infinite impulse response filter to the received measurement data to denoise the received measurement data.

15. The processing device of claim 13, wherein the received measurement data comprises:
standpipe pressure, flow rate, bit depth, surface weight on bit, and torque.

16. The processing device of claim 13, wherein the QR decomposition extracts a column from an ill-positioned matrix to form a well-positioned sub-matrix, which is used to solve a matrix inversion equation with numerical stability.

17. The processing device of claim 13, wherein respective coefficients of the at least some of the coefficients conform to the physical rules when corresponding values of the respective coefficients fall within corresponding valid ranges of values.

18. A method for predicting standpipe pressure comprising:
initializing, by a processing device, values of coefficients for a model;
creating, by the processing device, the model with the initialized coefficients as an enlisted model;
repeating, by the processing device, until a number of enlisted models is a preset number:
receiving measured data during a next time internal;
updating all candidate models based on the received measured data;
creating a candidate model based on the received measured data;
dropping the candidate model when at least one coefficient of the candidate model violates a physical rule; and
making the candidate model an enlisted model after the candidate model is learned, all coefficients of the candidate model comply with the physical rule, and a current number of enlisted models is less than the preset number;
predicting the standpipe pressure based on the enlisted models by applying a corresponding weight to a predicted standpipe pressure of each respective enlisted model to produce a respective weighted predicted standpipe pressure, the corresponding weight being based on an inverse of a variance of the respective enlisted model over a corresponding time interval;
adding the respective weighted predicted standpipe pressures to produce a sum of the weighted predicted standpipe pressures based on the preset number of the enlisted models; and
dividing the sum of the weighted predicted standpipe pressures by a sum of the weights to produce a predicted standpipe pressure based on the preset number of the enlisted models.

19. The method of claim 18, wherein the creating the candidate model based on the received measured data further comprises:
creating the candidate model only when at least a preset period of time has passed since creation of a last model.

20. The method of claim 19, wherein the creating the candidate model based on the received measured data further comprises:
creating the candidate model with default coefficients.

21. The method of claim 19, wherein the default coefficients have values equal to zero or have the values equal to values of coefficients of one of a last learned candidate model and an enlisted model of one or more enlisted models.

22. The method of claim 18, wherein the repeating further comprises:
when the candidate model outperforms an enlisted model of one or more enlisted models and the current number of the enlisted models equals the preset number, making the candidate model a new enlisted model that replaces the enlisted model of the one or more enlisted models.

23. A non-transitory machine-readable storage medium having instructions stored thereon, which when executed by a processor of a processing device, configure the processing device to perform a plurality of operations comprising:
initializing a Bayesian linear regressor, wherein priors for the Bayesian linear regressor are initialized based on previous drilling operations that used a same bottom hole assembly;
receiving measurement data associated with drilling a well in real time;
generating an online Bayesian linear regressor update using QR decomposition for a model;
determining whether coefficients of the online Bayesian regressor update violate physical rules;
in response to determining that at least some of the coefficients violate the physical rules, setting the at least some of the coefficients to a respective default value that is either zero or a positive value;
updating coefficients and uncertainty based on at least one of the online Bayesian linear regressor update and the setting of the at least some of the coefficients; and
visualizing the model.
